(19) United States
(12) Patent Application Publication
(10) Pub. No.: US 2015/0201531 A1
(43) Pub. Date: Jul. 16, 2015

(54) RF/EMI Shielding Fabric Security Sleeve/Pocket That Prevents The Wireless Device Inside From Communicating. "The Rapp IT Up"

(71) Applicant: Daniel K. Hilburn, SR., Mesa, AZ (US)

(72) Inventor: Daniel K. Hilburn, SR., Mesa, AZ (US)

(21) Appl. No.: 14/152,773

(22) Filed: Jan. 10, 2014

(51) Int. Cl. H05K 9/00; A45C 11/00

(52) U.S. Cl. CPC H05K 9/009; A45C 11/00

(57) ABSTRACT

The “Rapp It Up” is a RF/EMI shielding fabric security sleeve/pocket that prevents wireless communications is disclosed. Fabric wireless communications blocking products did not currently exist for personal and/or public private wireless devices such as cell phones, wireless computer tablets and laptop computers and wireless microchip imbedded (RFID) credit cards until I invented this device in January of 2013. Scientific laboratory electronic forensics has developed a product specifically for that field. They are generally limited to only 5 uses. The only thing that performs close to the “Rapp IT Up” is a solid metal mainly aluminum box. It does not breathe nor does it dissipate heat and is only designed for wireless data communicating (RFID) credit cards.

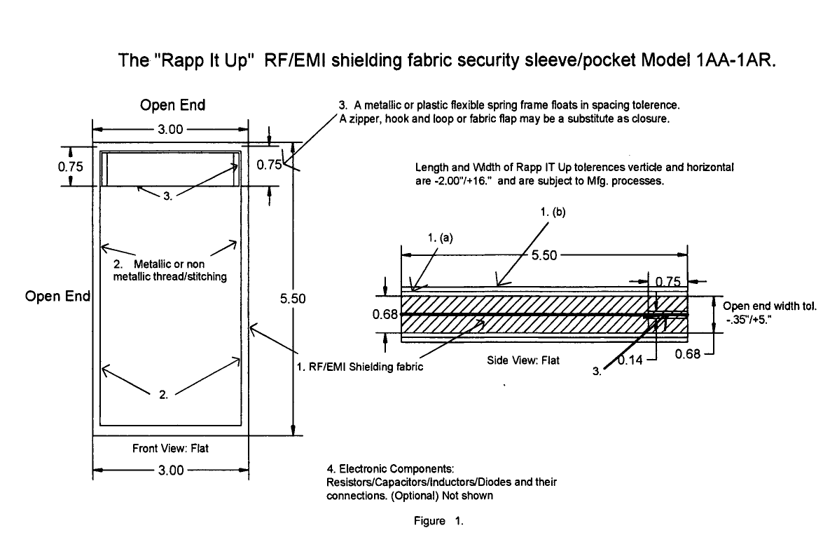

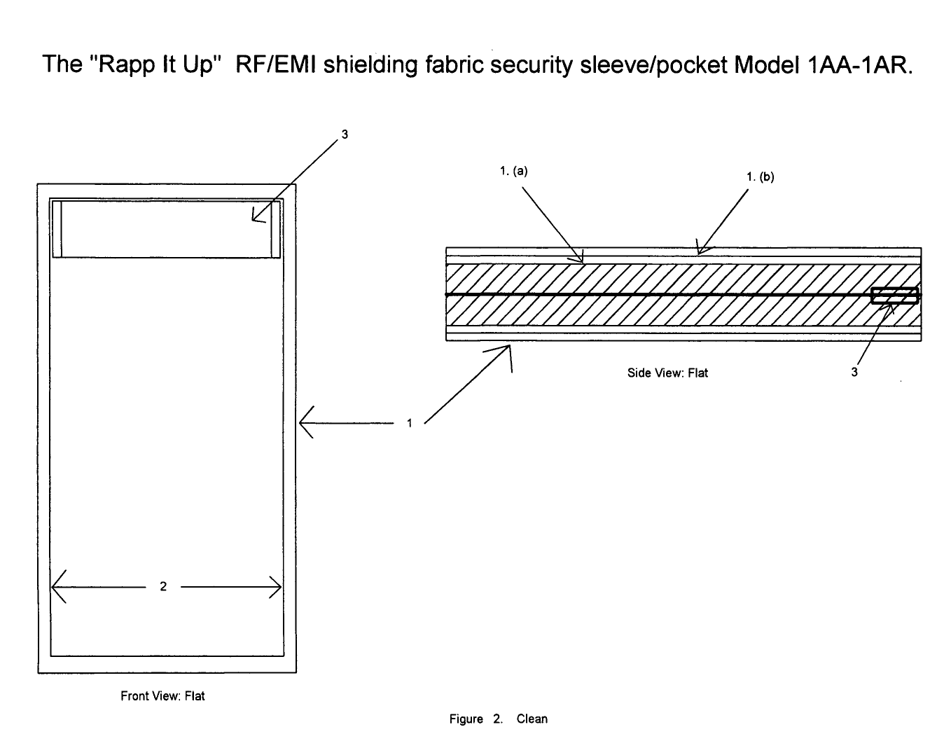

### TECHNICAL FIELD AND INDUSTRIAL APPLICABILITY OF THE INVENTION

This invention relates to the manufacture of a RF/EMI fabric pocket or sleeve that prevents communications between a wireless device and a signal transmission source(s) or any other device(s) while that device is inside the invention. The present invention relates particularly to the prevention of RF/EMI transmissions to and from a wireless device, such as cellular phones, tablets and laptop computers and radio frequency information device (RFID) enabled credit or debit cards from any other signal transmission source(s).

### BACKGROUND OF THE INVENTION

RF/EMI shielding pockets or sleeves are not widely used by the public for the protection of the data inside a wireless device, or as well as protecting the location of the user of the wireless device or protecting the user of the device from distracted driving. The pocket may have different shielding colors or textures of fabrics or closures to provide a variety in the styles and appearances they can provide to their users. Typically, the RF/EMI shielding products are only used in laboratory settings to shield sensitive RF/EMI signal transceivers or wireless devices.

Formerly, in constructing fabric RF/EMI security products, it was customary to construct a cage made from rigid metallic materials, those materials are then cut, formed and secure the materials into the shape of a box. These boxes utilized conventional materials that are metallic, stiff and rigid to give it a desired size to hold many different sized devices. Those materials would not be adorned, colored or embossed or otherwise form to add ornamentation to more closely resemble a pocket or a sleeve.

In recent years the RF/EMI shielding bags industry which is myopic has switched to some less rigid and in some cases a semi-transparent groups and is manufactured in a large sack where the device inside can be viewed in its active power state. They have never been manufactured for personal or public everyday use.

The myopic industry has not changed to manufactured pockets or sleeves having fabric as its base materials. The industry has kept to metallic coated heavy screen materials specifically for electronic forensics. The materials are screen like materials that are generally full of close quartered holes that do no effect the shielding properties of the cage. The metallic materials used are not typically given color or soft material to give it a desirable property. The outer layer is heavy and generally industrial in appearance.

### BRIEF DESCRIPTION OF THE SEVERAL VIEWS

### Rapp IT Up RF/EMI Security Sleeve

Drawing: RAPP_IT_UP_MODEL_{—}1AA_{—}1AR_{—}2014_D_REV_{—}3_DWG_MARKED_UP_FIGURE_{—}1

Drawing: RAPP_IT_UP_MODEL_{—}1AA_{—}1AR_{—}2014_D_REV_{—}3_DWG_CLEAN_FIGURE_{—}2

View 1; Depicts the (lying flat FRONT) and (lying flat on its SIDE) views respectively.

What is claimed is:

1. The RF/EMI shielding fabric pocket article of various colors, layers and textures comprising; layers of metallic embedded or coated fabrics; and a closure device; metallic or plastic spring frame, metal coated or impregnated zipper, hook and loop (Velcro type device) or shielding fabric flap.

2. The RF/EMI shielding fabric pocket article of claim 1, wherein said metallic coated or embedded or wire mesh embedded fabric RF/EMI shielding pocket layered device material comprises a breathable shielding fabric, RF/EMI shielding pocket that is coated or embedded with a metal or combinations of metals.

3. The RF/EMI shielding fabric pocket article of claim 2, wherein said shielding fabric materials comprises a layered RF/EMI shielding fabric that resists RF/EMI transmissions or signal penetration.

4. The RF/EMI shielding fabric pocket article of claim 3, Wherein said metal coated or embedded fabric materials is selected from various groups of Silver Coated Nylon Ripstop, Cotton Poly Synthetic embedded with wire mesh, Silver, Nickel or Copper coated Radio Screen, Wire Mesh Embedded Staticot and/or Wire Mesh embedded ArgenMesh or other Metal Coated or Wire Mesh Embedded materials.

5. The RF/EMI shielding fabric pocket article of claim 4, wherein said article has a visible color, and said top layer of fabric provides a percentage of some or all of the signal shielding of the article, and said inner layers of fabric provide additional significant contribution to the RF/EMI shielding characteristics of the article.

6. The RF/EMI shielding fabric pocket article of claim 5, wherein said metallic coated or embedded layered RF/EMI shielding pocket is comprised of metallic coated or embedded layers of fabrics and a closure.

7. The RF/EMI shielding layered fabric pocket article of claim 6, wherein said metallic coated fabric material is not substantially comprised of silver, nickel or copper.

8. The RF/EMI shielding fabric pocket article of claim 7, wherein said metallic coated or embedded layered fabric pocket is selected from the group consisting of Silver Coated Nylon Ripstop, Cotton Poly Synthetic embedded with wire mesh, Silver, Nickel or Copper coated Radio Screen, Wire Mesh Embedded Staticot and/or Wire Mesh embedded ArgenMesh or other Metal Coated or Wire Mesh embedded materials.
